(19) United States
(12) Patent Application Publication
(10) Pub. No.: US 2015/0263161 A1
(43) Pub. Date: Sep. 17, 2015

(54) SEMICONDUCTOR STORAGE DEVICE AND METHOD OF MANUFACTURING THE SAME

(71) Applicant: KABUSHIKI KAISHA TOSHIBA, Minato-ku (JP)

(72) Inventor: Atsushi YAGISHITA, Yokohama (JP)

(73) Assignee: KABUSHIKI KAISHA TOSHIBA, Minato-ku (JP)

(21) Appl. No.: 14/581,156

(22) Filed: Dec. 23, 2014

Related U.S. Application Data
(60) Provisional application No. 61/951,928, filed on Mar. 12, 2014.

(51) Int. Cl. H01L 29/788; H01L 21/28; H01L 21/02; H01L 29/66; H01L 29/06

(52) U.S. Cl. CPC H01L 29/788; H01L 29/66825; H01L 29/0692; H01L 21/02532; H01L 21/02636; H01L 21/28273

(57) ABSTRACT

A semiconductor storage device includes a semiconductor substrate; an active region provided in the semiconductor substrate and extending in a first direction; and a plurality of gates provided above the active region and extending in a second direction. The gates are provided with a stack of a floating gate and a control gate, and an elevated portion is provided above the active region disposed between adjacent gates.

### CROSS-REFERENCE TO RELATED APPLICATION(S)

This application is based upon and claims the benefit of priority from U.S. Provisional Patent Application No. 61/951,928, filed on, Mar. 12, 2014 the entire contents of which are incorporated herein by reference.

### FIELD

Embodiments disclosed herein generally relate to a semiconductor storage device and a method of manufacturing the same.

### BACKGROUND

In a semiconductor storage device such as the so-called fringe-cell type NAND flash memory, in which a source•drain region is formed by forming an inversion layer using the fringe field coming from the control gate without forming an impurity diffusion layer in a source•drain region of a memory-cell transistor, the source•drain region induced by the fringe field tends to have high resistance. Thus, the memory-cell transistors faced a problem of failing to obtain sufficient ON current. High levels of cross talk between the adjacent elements was another problem.

### BRIEF DESCRIPTION OF THE DRAWINGS

FIG. 1 is one example of an equivalent circuit diagram partially illustrating a memory-cell array formed in a memory-cell region of a NAND flash memory device of one embodiment.

FIG. 2 is one schematic example of a plan view illustrating a layout pattern of the memory cell region in part.

FIG. 3 is one example of a perspective view illustrating a three-dimensional structure of region D indicated in FIG. 2.

FIGS. 4A to 4D illustrate examples of typical variations in the shapes of an elevated portion of one embodiment.

FIGS. 5A, 5B, and 5C illustrate examples of effects of the shapes of the elevated portion of one embodiment.

FIGS. 6 to 15C are examples of figures for describing a method of manufacturing a semiconductor storage device of one embodiment.

### DESCRIPTION

A semiconductor storage device includes a semiconductor substrate; an active region provided in the semiconductor substrate and extending in a first direction; and a plurality of gates provided above the active region and extending in a second direction. The gates are provided with a stack of a floating gate and a control gate, and an elevated portion is provided above the active region disposed between adjacent gates.

### Embodiment

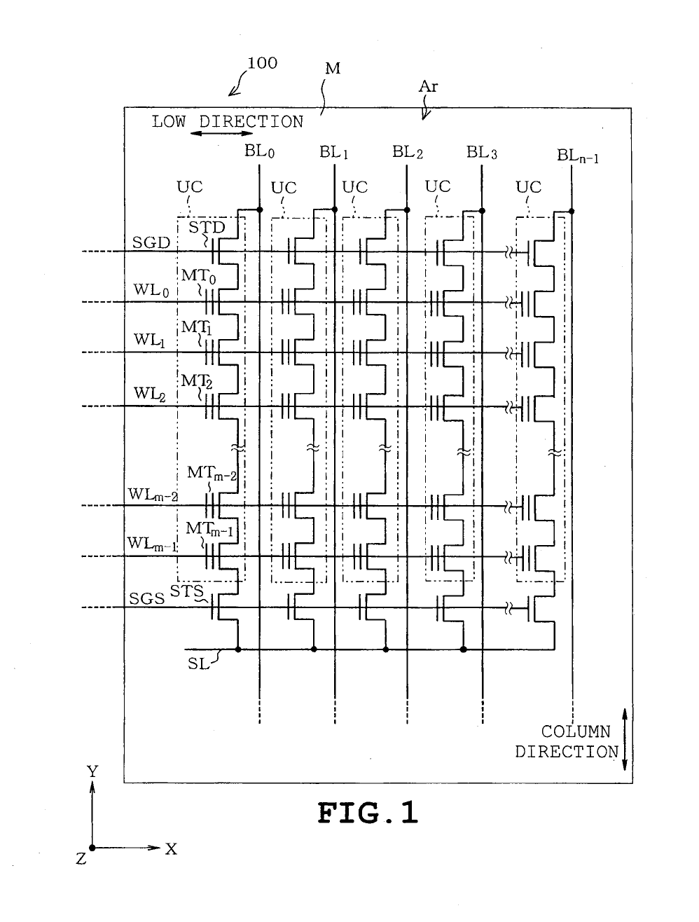

Embodiments of a semiconductor storage device is described hereinafter through a NAND flash memory device application with reference to FIG. 1 to FIGS. 15A, 15B, and 15C. In the following description, elements provided with identical function and structure are identified with identical reference symbols. The drawings are schematic, and do not necessarily reflect the actual measurements of the features such as the correlation of thickness to planar dimensions and the ratio of thicknesses of each of the layers. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. In the following description, XYZ orthogonal coordinate system is used for ease of explanation. In the coordinate system, the X direction and the Y direction indicate directions parallel to the surface of the semiconductor substrate and are orthogonal to one another. The X direction indicates the direction in which word lines WL extend and the Y direction orthogonal to the X direction indicates the direction in which bit lines BL extend. The direction orthogonal to both the X direction and the Y direction are referred to as the Z direction.

First, a description will be given on the structures of NAND flash memory device 100 of the present embodiment.

FIG. 1 is one example of a partial equivalent circuit diagram of memory-cell array formed in a memory-cell region of NAND flash memory device 100 of the present embodiment. As shown in FIG. 1, NAND flash memory device 100 is provided with memory cell array Ar configured by multiplicity of memory cells arranged in a matrix.

Memory cell array Ar located in memory cell region M includes unit memory cells UC. Unit memory cells UC include select-gate transistors STD connected to bit lines BL₀ to BLₙ₋₁ and select-gate transistors STS connected to source lines SL. Between select-gate transistors STD and STS, m (m=2^{k}, m=32 for example) number of series connected memory-cell transistors MT₀ to MTₘ₋₁ are disposed.

Unit memory cells UC form a memory-cell block and the memory-cell blocks form memory-cell array Ar. That is, a single block comprises n number of unit memory cells UC, aligned along the row direction (X direction as viewed in FIG. 1). Memory-cell array Ar is formed of blocks aligned along the column direction (Y direction as viewed in FIG. 1). FIG. 1 only shows one block for simplicity.

The gates of select-gate transistors STD are connected to control line SGD. The control gates of the m^{th} memory-cell transistors MTₘ₋₁ connected to bit lines BL₀ to Blₙ₋₁ are connected to word line WLₘ₋₁. The control gates of the third memory-cell transistors MT₂ connected to bit lines BL₀ to Blₙ₋₁ are connected to word line WL₂. The control gates of second memory-cell transistors MT₁ connected to bit lines BL₀ to Blₙ₋₁ are connected to the second word line WL₁. The control gates of first memory-cell transistors MT₀ connected to bit lines BL₀ to Blₙ₋₁ are connected to first word line WL₀. The gates of select-gate transistors STS connected to source lines SL are connected to control line SGS. Control lines SGD, word lines WL₀ to WLₘ₋₁, control lines SGS and source lines SL each intersect with bit lines BL₀ to Blₙ₋₁. Bit lines BL₀ to Blₙ₋₁ are connected to a sense amplifier (not shown).

Gate electrodes of select-gate transistors STD of the row-direction aligned unit memory cells UC are electrically connected by common control line SGD. Similarly, gate electrodes of select-gate transistors STS of the row direction aligned unit memory cells UC are electrically connected by common control line SGS. The source of each select-gate transistor STS is connected to common source line SL. Gate electrodes of memory-cell transistors MT₀ to MTₘ₋₁ of the row-direction aligned unit memory cells UC are each electrically connected by word line WL₀ to WLₘ₋₁, respectively.

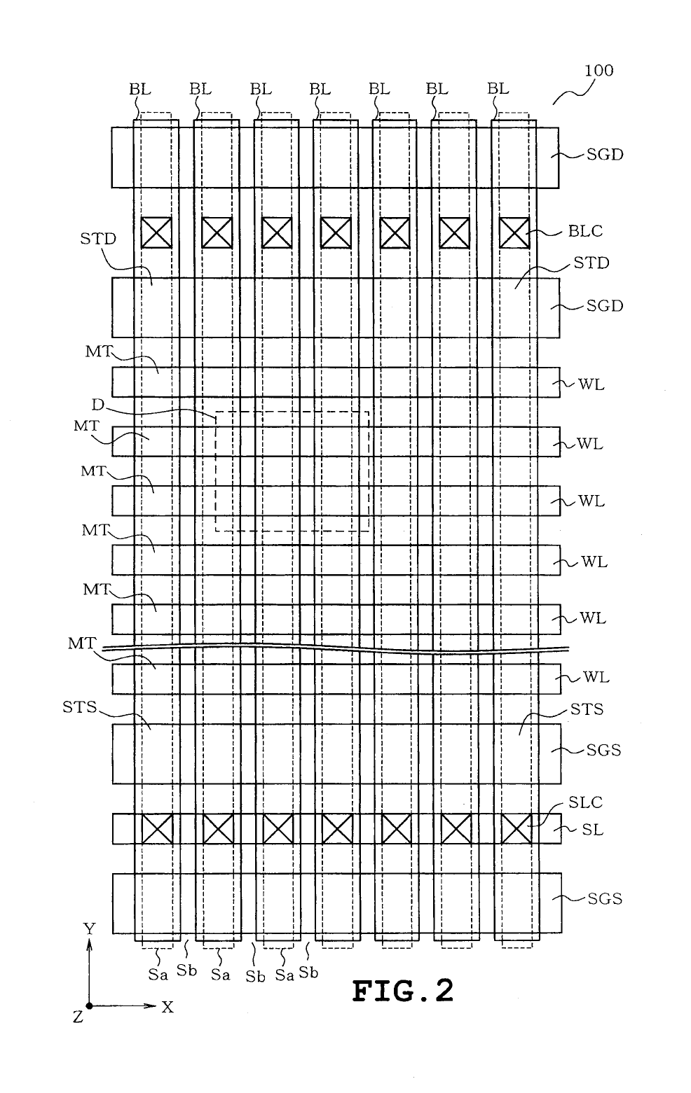

FIG. 2 is one schematic example of a plan view illustrating a planar layout of memory cell region M in part. Bit lines BL₀ to Blₙ₋₁ are also hereinafter referred to as bit line (s) BL. Word lines WL₀ to WLₘ₋₁ are also hereinafter referred to as word line (s) WL. Memory-cell transistors MT₀ to MTₘ₋₁ are also hereinafter referred to as memory-cell transistor(s) MT.

As shown in FIG. 2, source lines SL, control lines SGS, word lines WL, and control lines SGD each run in the X direction and are spaced from one another in the Y direction. Bit lines BL are aligned along the Y direction and isolated from one another in the X direction by a predetermined distance.

Element isolation regions Sb run in the Y direction as viewed in the figures. Element isolation region Sb takes an STI (shallow trench isolation) structure in which the trench is filled with an insulating film. Element isolation regions Sb are spaced from one another in the X direction by a predetermined distance. Thus, element isolation regions Sb isolate element regions Sa, formed in a surface layer of semiconductor substrate 2 along the Y direction, in the X direction. In other words, element isolation region Sb is located between element regions Sa, meaning that the semiconductor substrate, is delineated into element regions Sa also referred to as an active region by element isolation region Sb.

Word lines WL extend in a direction orthogonal to element regions Sa (the X direction as viewed in FIG. 2). Word lines WL are spaced from one another in the Y direction as viewed in the figures by a predetermined distance. In element region Sa located at the intersection with word line WL, memory-cell transistor MT is disposed. The Y-direction adjacent memory-cell transistors MT form a part of a NAND string (memory-cell string).

In element region Sa located at the intersection with control lines SGS and SGD, select-gate transistors STS and STD are disposed. Select-gate transistors STS and STD are disposed Y-direction adjacent to the outer sides of memory-cell transistors MT located at both end portions of the NAND string.

Select-gate transistors STS connected to source line SL are aligned in the X direction and select gate electrodes SG of select-gate transistors STS are electrically interconnected by control line SGS. Select gate electrode SG of select-gate transistor STS is formed in element region Sa intersecting with control line SGS. Source contact SLC is provided at the intersection of source line SL and bit line BL.

Select-gate transistors STD are aligned in the X direction as viewed in the figures and select gate electrodes SG of select-gate transistors STD are electrically interconnected by control line SGD. Select gate electrode SG of select-gate transistor STD is formed in element region Sa intersecting with control line SGD. Bit line contact BLC is provided in element region Sa located between the adjacent select-gate transistors STD.

In the present embodiment, an impurity diffusion layer is not provided in a source•drain region of semiconductor substrate 10 located at both sides of memory gate electrodes MG for memory-cell transistors MT of NAND flash memory device 100. Source•drain region is formed by forming an inversion layer in the semiconductor substrate surface by a fringe field coming from memory gate electrode MG (control gate electrode) during device operation.

The foregoing description outlines the basic structures of NAND flash memory device 100 to which the present embodiment is directed.

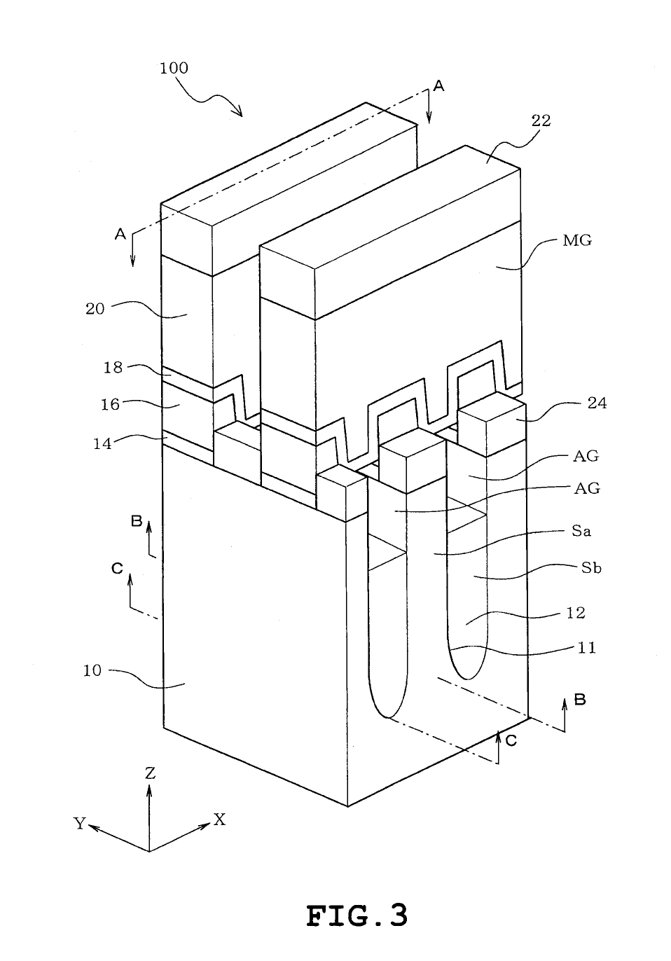

Next a description will be given in more detail on the structures of NAND flash memory device 100 of the present embodiment with reference to FIG. 3. FIG. 3 is one example of a perspective view illustrating a three-dimensional structure of region D indicated in FIG. 2. Semiconductor substrate 10 is provided with element isolation regions Sb. Element isolation region Sb has element isolation trench 11 formed therein and element isolation trench 11 is filled with element isolation insulating film 12. A silicon substrate may be used for example as semiconductor substrate 10. Element isolation insulating film may be formed of for example a silicon oxide film. Semiconductor substrate 10 delineated by element isolation regions Sb serve as element region Sa. Memory gate electrodes MG are formed above semiconductor substrate 10. Memory gate electrode MG has, as named from semiconductor substrate 10 side, tunnel film 14, floating gate electrode 16, interelectrode insulating film 18, control gate electrode 20, and cap film 22. Tunnel film 14 may be formed of for example a silicon oxide film. Interelectrode insulating film 18 is formed of an ONO (Oxide-Nitride-Oxide) film which is a stack of a silicon oxide film/silicon nitride film/silicon oxide film. An upper portion of element isolation insulating film 12 within element isolation region Sb is partially removed to form an air gap AG (unfilled gap) between element regions Sa and below interelectrode insulating film 18 located between element regions Sa. Air gap AG extends in the Y direction as viewed in the figures.

Element region Sa is defined by element isolation region Sb and memory gate electrode MG and has a substantially rectangular surface. Elevated portion 24 is formed in element region Sa. The bottom surface of elevated portion 24 is a substantially rectangular element region Sa and elevated portion (uprising portion) in contact therewith is formed so as to elevate element region Sa. The upper surface of elevated portion 24 is higher than the surface of element region Sa and, in one embodiment, is approximately mid height of floating gate electrode 16. Elevated portion 24 is disposed between memory gate electrodes MG and serves as source•drain region of memory-cell transistor MT. Elevated portion 24 is formed of, for example, silicon crystals grown on element region Sa (semiconductor substrate 10) by selective epitaxial method. Alternatively, an amorphous silicon film may be used which is later crystallized. The side surfaces of memory gate electrodes FG are covered by thin sidewall insulating films in the actual structure. Thus, the sidewall insulating film (later described as sidewall insulating film 26) exists between elevated portion 24 and memory gate electrode MG and provides insolation between the two. In FIG. 3, the sidewall insulating film is not illustrated to provide good visibility. A silicon oxide film, a silicon nitride film, or the like may be used for example as a sidewall insulating film.

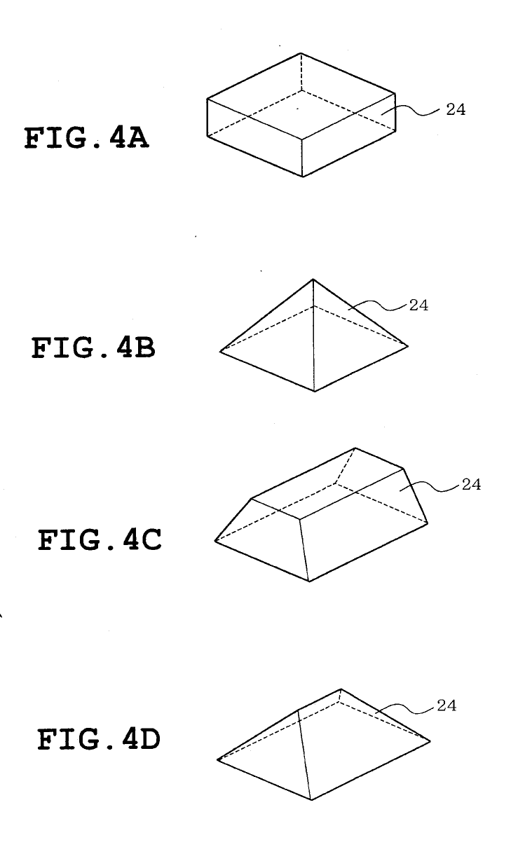

Elevated portion 24 may form in different shapes because of facet. FIGS. 4A to 4D are examples of typical variations in the shapes of elevated portion 24. FIG. 4A, FIG. 4B, FIG. 4C, and FIG. 4D are examples of perspective views of elevated portions 24 and illustrate a quadrangular prism shape, a quadrangular pyramid shape, quadrangular frustum pyramid shape, and a hipped roof shape, respectively. These shapes may be controlled by the film forming conditions, or the like, employed when forming the silicon film.

The quadrangular prism shape illustrated in FIG. 4A represents the shape of the film formed under conditions that does not produce a facet during selective epitaxial growth of silicon. The quadrangular prism shape possesses an upper surface portion and a side surface portion. This shape may also be obtained by forming an amorphous silicon film and crystallizing the same by thermal treatment instead of the selective epitaxial growth of silicon.

The quadrangular pyramid shape illustrated in FIG. 4B represents the shape of the film formed under conditions that produces a facet during selective epitaxial growth of silicon in which the shape of the surface of element regions Sa serving as the bottom surface is a square. The quadrangular pyramid shape possesses four sloped surface portions. The quadrangular frustum pyramid shape illustrated in FIG. 4C represents the shape of the film formed under conditions that produces a facet during selective epitaxial growth of silicon in which the growth is terminated before a ridge is formed by two or more sloped surfaces formed by the facet. The quadrangular frustum pyramid shape possesses an upper surface portion and four sloped surface portions. The hipped roof shape illustrated in FIG. 4D represents the shape of the film formed under conditions that produces a facet during selective epitaxial growth of silicon in which the shape of the surface of element regions Sa serving as the bottom surface is a rectangular shape other than square. The hipped roof shape possesses four sloped surfaces. The hipped roof shape possesses two sloped surface portions forming a ridge and two sloped surface portions disposed so as to slice the ridge. The facet angle may vary depending upon the conditions in which the silicon film is formed, the film material contacting the silicon film (the material of the above described sidewall insulating film for example in the present embodiment), or the like.

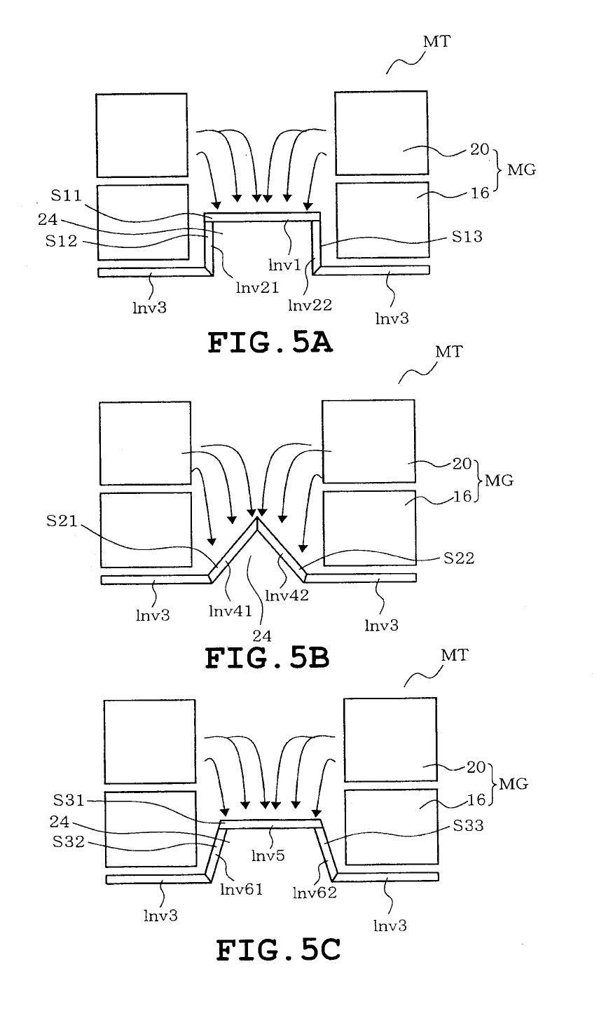

Next, a description will be given on the effects of the different shapes of elevated portions 24 formed between memory gate electrodes MG with reference to FIGS. 5A, 5B, and 5C.

FIG. 5A is one example of a vertical cross-sectional view for explaining the inverted state of the silicon surface when elevated portion 24 is a facetless quadrangular prism. The figure illustrates memory gate electrodes MG being disposed on both sides of elevated portion 24. Elevated portion 24 is disposed between the adjacent memory gate electrodes MG. Elevated portion 24 serves as a source•drain region of memory-cell transistor MT in which memory gate electrode MG serves as a gate electrode.

No impurity region for forming source•drain diffusion layer is formed in elevated portion 24. Memory gate electrode MG is provided with floating gate electrode 16 and control gate electrode 20 formed above semiconductor substrate 10 via tunnel insulating film 14.

Elevated portion 24 has a quadrangular prism shape as illustrated in the figure and possesses upper surface portion S11 being parallel to the surface of semiconductor substrate 10 and side surface portions S12 and S13 orthogonal to semiconductor substrate 10. When voltage is applied to control gate 20, fringe field coming from control gate electrode 20 is applied to the surface of elevated portion 24 and forms inversion layer Inv1 in surface portion S11 of elevated portion 24.

A weak level of fringe field coming from control electrode 20 is applied on side surface portions S12 and S13 of elevated portion 24 to form weakly inverted inversion layers Inv21 and Inv22. Inversion layer Inv3 is formed in semiconductor substrate 10 below floating gate electrode 16 by an electric field coming from floating gate electrode 16. The potential of electric field is elevated by the coupling of control gate electrodes 20 on which voltage is applied. Inversion layers Inv become electrically conductive and serve as conductor portions. Inversion layers Inv1, Inv21, and Inv22 serve as a source•drain portion of memory-cell transistor MT. Inversion layer Inv3 serves as a channel portion of memory-cell transistor MT. When a predetermined level of voltage is applied to control gate electrode 20, inversion layers Inv1, Inv21, Inv22, and Inv3 become interconnected and electrical connection is established from the source•drain portion to the channel portion. The resistances of weakly inverted inversion layers Inv21 and Inv22 are high. Upper surface portion S11 is elevated from the surface of element region Sa to become closer to control gate electrode 20. Thus, upper surface portion S11 is strongly affected by the fringe field and a strong inversion layer is formed. As a result, the resistance of inversion layer Inv1 portion becomes lower as compared to an inversion layer being formed in element region Sa. The ON current of memory-cell transistor MT relies on the resistances of inversion layers Inv1, Inv21, and Inv22. The resistances of inversion layers Inv21, Inv22 are relatively high. However, it is possible to control the overall resistance by, for example, controlling the height of the elevation of elevated portion 24.

FIG. 5B is one example of a vertical cross-sectional view for explaining the inverted state of elevated portion 24 having a facet and having a triangular cross section in the gate length direction of memory-cell transistor MT. FIG. 5B is one example of a vertical cross-sectional view for explaining the inverted state of elevated portion 24 having a facet and having a quadrangular pyramid shape or a hipped roof shape in three dimension. Elevated portion 24 has a triangular cross section as illustrated in the figure and possesses upper surface portions S21 and S22 being disposed at a certain angle with respect to the surface of semiconductor substrate 10. Upper surface portions S21 and S22 are obliquely formed facet planes. Upper surface portions S21 and S22 are formed into a ridge shape having a pointed top.

When voltage is applied to control electrode 20, fringe field coming from control electrode 20 is applied on the surface of elevated portion 24 to form inversion layers Inv41 and Inv42 in upper surface portions S21 and S22. Inversion layer Inv3 is formed in semiconductor substrate 10 below floating gate electrode 16 by an electric field coming from floating gate electrode 16. Inversion layers Inv41 and Inv42 become electrically conductive and serve as conductor portions. Inversion layers Inv41 and Inv42 serve as a source•drain region of memory-cell transistor MT. Inversion layer Inv3 serves as a channel portion of memory-cell transistor MT. When a predetermined level of voltage is applied to control gate electrode 20, inversion layers Inv3, Inv41, and Inv42 become interconnected and electrical connection is established from the source•drain portion to the channel portion. A weakly inverted inversion layer Inv2 illustrated in FIG. 5A does not exist in this case and thus, there are no high-resistance portions. As a result, ON current of memory-cell transistor MT is not lowered. Upper surface portions S21 and S22 are elevated from the surface of element region Sa to become closer to control gate electrode 20. Thus, upper surface portions S21 and S22 are strongly affected by the fringe field and a strong inversion layer is formed. As a result, the resistance of inversion layer portion becomes lower as compared to an inversion layer being formed in element region Sa. Thus, ON current of memory-cell transistor MT is increased.

FIG. 5C is one example of a vertical cross-sectional view for explaining the inverted state of elevated portion 24 having a facet and having a trapezoid cross section in the gate length direction of memory-cell transistor MT. Elevated portion 24 has a trapezoid cross section as illustrated in the figure and possesses upper surface portion S31 parallel with the surface of semiconductor substrate 10. Elevated portion 24 possesses upper surface portions S32 and S33 being disposed at a certain angle with respect to upper surface portion S31. Upper surface portions S32 and S33 are obliquely formed facet planes.

When voltage is applied to control electrode 20, fringe field coming from control electrode 20 is applied on the surface of elevated portion 24 to form inversion layer Inv5 in upper surface portion S31 and inversion layers Inv61 and Inv62 in upper surface portions S32 and S33. Inversion layer Inv3 is formed in semiconductor substrate 10 below floating gate electrode 16 by an electric field coming from floating gate electrode 16. Inversion layers Inv3, Inv5, Inv61 and Inv62 become electrically conductive and serve as conductor portions. Inversion layers Inv5, Inv61 and Inv62 serve as a source•drain region of memory-cell transistor MT. Inversion layer Inv3 serves as a channel portion of memory-cell transistor MT. When a predetermined level of voltage is applied to control gate electrode 20, inversion layers Inv3, Inv5, Inv61 and Inv62 become interconnected and electrical connection is established from the source•drain portion to the channel portion. A weakly inverted inversion layer Inv21 and Inv22 illustrated in FIG. 5A do not exist in this case and thus, there are no high-resistance portions. As a result, ON current of memory-cell transistor MT is not lowered. Upper surface portions S31, S32, and S33 are elevated from the surface of element region Sa to become closer to control gate electrode 20. Thus, upper surface portions S31, S32, and S33 are strongly affected by the fringe field and strong inversion layers are formed. As a result, the resistance of inversion layer portion becomes lower as compared to an inversion layer being formed in element region Sa. Thus, ON current of memory-cell transistor MT is increased.

In the embodiment described above, the resistance of the source•drain region is lowered by inversion layer Inv formed in the surface of elevated portion 24 formed near control gate electrode 20 and thereby increasing the ON current of memory-cell transistor MT. Further, by disposing elevated portion 24 between memory gate electrodes MG, it is possible to provide a block between memory gate electrodes MG and inhibit cross talk of adjacent elements. Still further, because impurities are not introduced into source•drain region, a thermal treatment for activating the impurities is eliminated. As a result, it is possible to inhibit metal contamination originating from the control gate electrode. Yet, further, inversion layer Inv formed in the upper surface of elevated portion 24 serves as the source•drain region. As a result, effective gate length (Leff)) of memory-cell transistor is increased which allows the short channel effect to be inhibited.

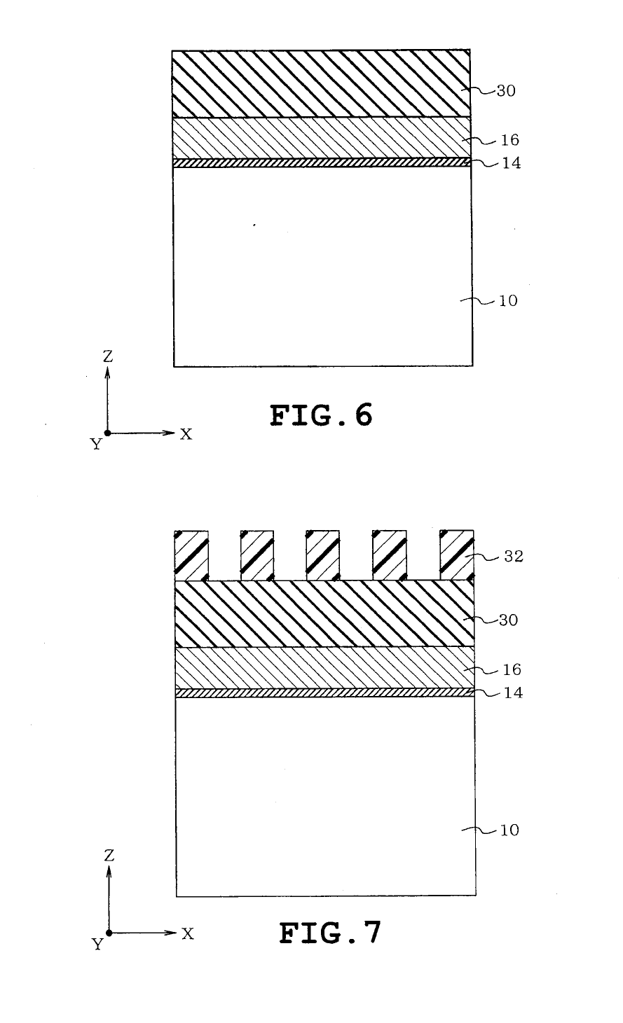

(Manufacturing Method) A method of manufacturing NAND flash memory device 100 of the present embodiment will be described hereinafter with reference to FIGS. 6 to 15.

As illustrated in FIG. 6, tunnel insulating film 14 is formed above semiconductor substrate 10. FIG. 6 is one example of a vertical cross sectional view taken along line AA in FIG. 3. A silicon oxide film may be used for example as tunnel insulating film 14 and may be formed for example to be approximately 7.5 nm thick by thermal oxynitridation. Next, polysilicon is formed for example as a film serving as floating gate electrode 16. Polysilicon may be formed to be approximately 50n by CVD. This is followed by formation of sacrificial film 30. A silicon nitride film may be used for example as sacrificial film 30.

Next, as illustrated in FIG. 7, a patterned mask film 32 is formed using lithography or sidewall transfer process. FIG. 7 is one example of a vertical cross sectional view taken along line AA of FIG. 3. A resist film or a silicon oxide film may be used for example as mask film 32.

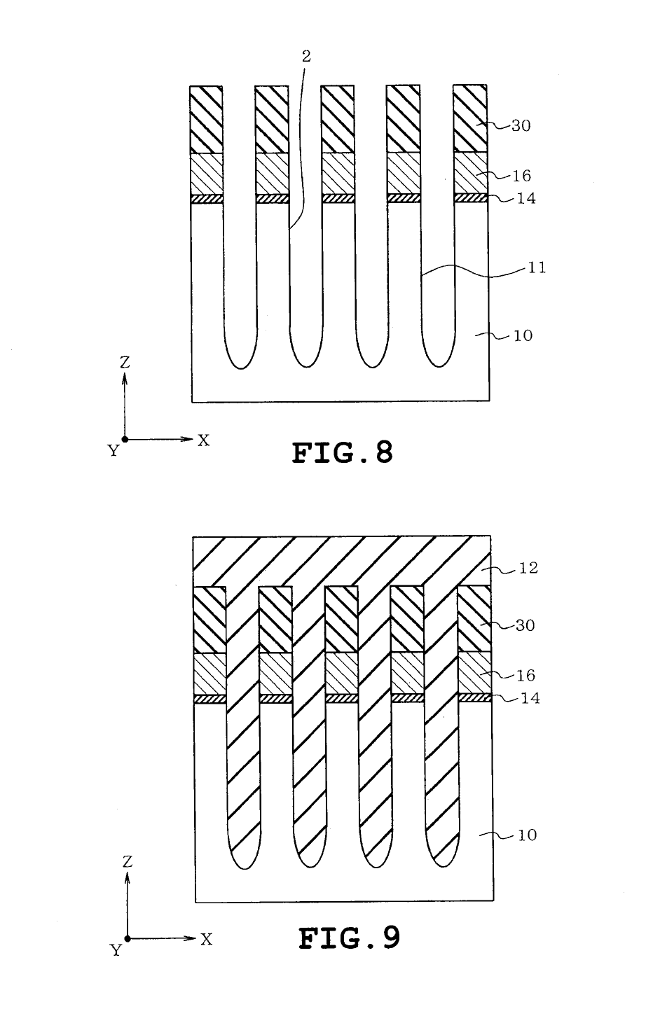

Then, as illustrated in FIG. 8, using mask film 32 as a mask, sacrificial film 30, floating gate electrode 16, tunnel film 14, and semiconductor substrate 10 are etched using RIE (Reactive Ion Etching) under anisotropic conditions to transfer the pattern of mask film 32. FIG. 8 is one example of a vertical cross sectional view taken along line AA of FIG. 3. Mask film 32 is thereafter removed. Element isolation trenches 11 having a predetermined depth are formed into semiconductor substrate 10. For example, the depth of element isolation trenches 11 is approximately 200 nm.

As illustrated in FIG. 9, a silicon oxide film is formed along the inner wall of element isolation trench 11. Then, polysilazane (PSZ) film is coated into element isolation trench 11 which is transformed to a silicon oxide film by thermal treatment to fill element isolation trench 11 with element isolation insulating film 12. FIG. 9 is one example of a vertical cross sectional view taken along line AA of FIG. 3. The upper surface of element isolation insulating film 12 is planarized by CMP (Chemical Mechanical Polishing).

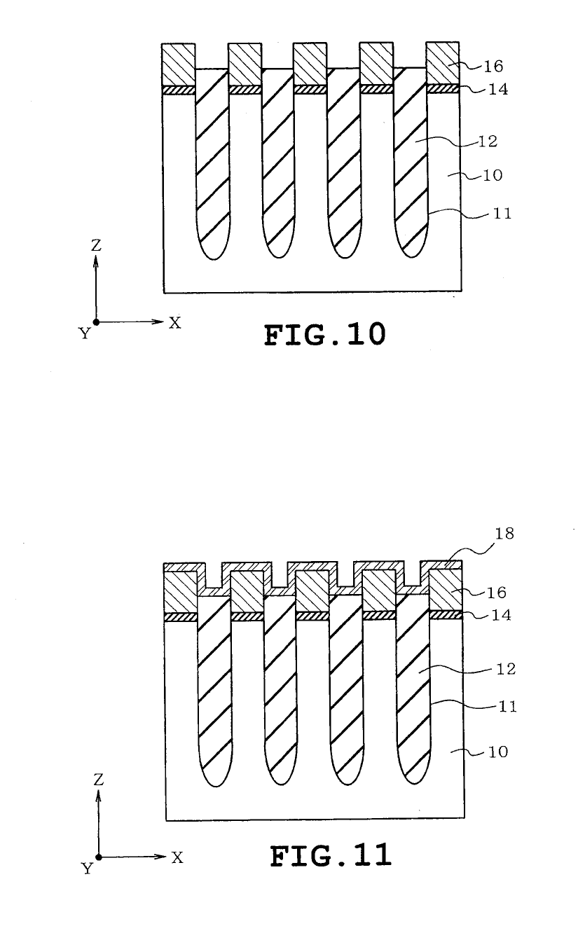

As illustrated in FIG. 10, element isolation insulating film 12 is etched so that the upper surface of element isolation insulating film 12 is lower than the upper surface of floating gate electrode 16 so as to be approximately level with the mid-height of floating gate electrode 16. FIG. 10 is one example of a vertical cross sectional view taken along line AA of FIG. 3. Diluted fluoric acid may be used for example in the etching. Sacrificial film 30 is thereafter removed. Hot phosphoric acid may be used for example in removing sacrificial film 30.

Interelectrode insulating film 18 is formed as illustrated in FIG. 11. FIG. 11 is one example of a vertical cross sectional view taken along line AA of FIG. 3. An ONO film may be used for example as interelectrode insulating film 18. The ONO film may be formed for example by forming a silicon oxide film, a silicon nitride film, and a silicon oxide film one after another using CVD. Interelectrode insulating film 18 is formed conformally along a three-dimensional surface formed by floating gate electrode 16 and element isolation insulating film 12b.

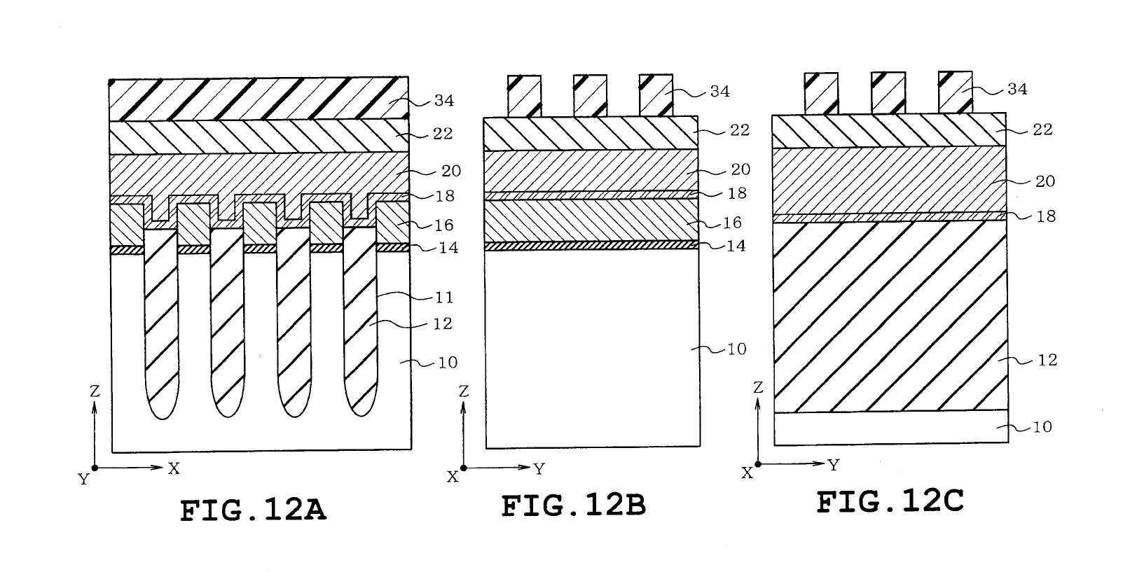

As illustrated in FIGS. 12A, 12B, and 12C, polysilicon serving as control gate electrode 20 is formed above interelectrode insulating film 18. FIG. 12A, FIG. 12B, and FIG. 12C are examples of vertical cross sectional views taken along line AA of FIG. 3, line BB of FIG. 3, and line CC of FIG. 3. Next, cap film 22 is formed. A silicon nitride film may be used for example as cap film 22 and may be formed for example by CVD. Mask film 34 is formed above cap film 22 using for example lithography or sidewall transfer process. A resist film or a silicon oxide film may be used for example as mask film 34.

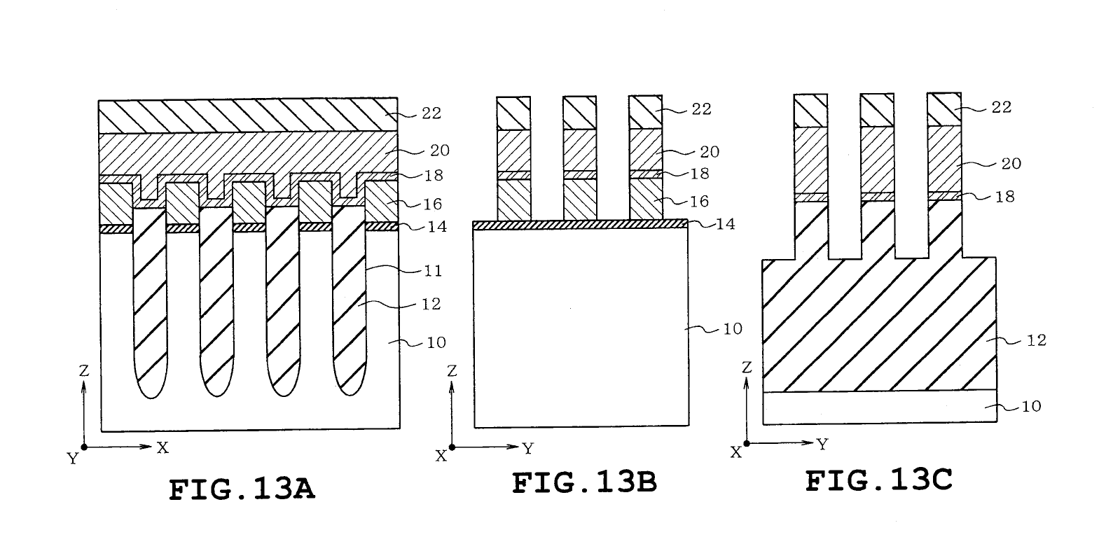

As illustrated in FIGS. 13A, 13B, and 130, cap film 22, control gate electrode 20, interelectrode insulating film 18, and floating gate electrode 16 are etched by RIE under anisotropic conditions using mask film 34 as a mask. Word lines WL are formed by the etching. The etching progresses midway through element isolation insulating film 12 in the portion illustrated in FIG. 13C to form gaps. Mask film 34 is thereafter removed.

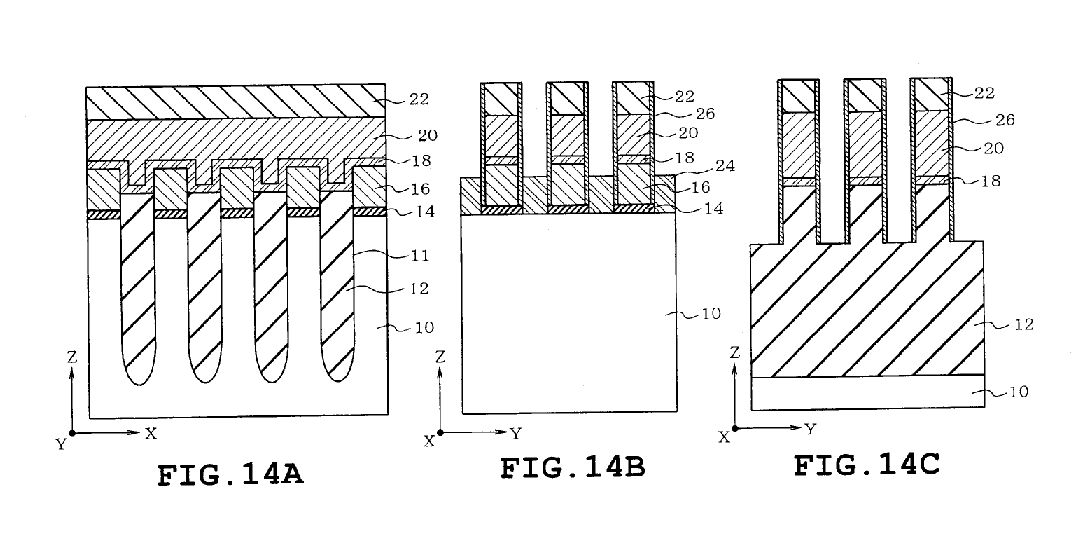

As illustrated in FIGS. 14A, 14B, and 14C, sidewall insulating film 26 is formed, followed by RIE anisotropic etching for leaving sidewall insulating film 26 along the side surfaces of memory gate electrode MG. Tunnel film 14 exposed above the surface of semiconductor substrate 10 is also removed in the etching. After the surface of semiconductor substrate 10 is exposed, elevated portions 24 are formed on the exposed surface of semiconductor substrate 10. Formation of elevated portions 24 is carried out for example by selective epitaxial growth of silicon. It is thus, possible to selectively form elevated portions 24 on the exposed surface of semiconductor substrate 10. The selective epitaxial growth of silicon is carried out under conditions that do not introduce impurities into silicon. Further, impurities are not doped for formation of source•drain region after the selective epitaxial growth of silicon.

It is possible to control the shape of elevated portion 24 by controlling the presence/absence of facet, facet angle, thickness of film growth, or the like by adjustment of conditions applied in the selective epitaxial growth of silicon. The present embodiment was described through examples of elevated portions 24 having, but not limited to, quadrangular prism shape, quadrangular pyramid shape, quadrangular frustum pyramid shape, and a hipped roof shape as illustrated in FIGS. 4A to 4D. FIG. 14B illustrates elevated portion 24 envisaging a quadrangular prism shape as one example.

Further, elevated portion 24 may be formed by the following method instead of the selective epitaxial growth of silicon described above. First, amorphous silicon is formed by CVD. Then, the amorphous silicon is partially crystallized by annealing and the uncrystallized portions are removed by etching. The etching may be a wet etching using a liquid mixture of fluoric acid, nitric acid, and acetic acid. Dry cleaning using chloric acid (HCl) may be used in the removal. Elevated portion 24 can be formed by the above described process steps.

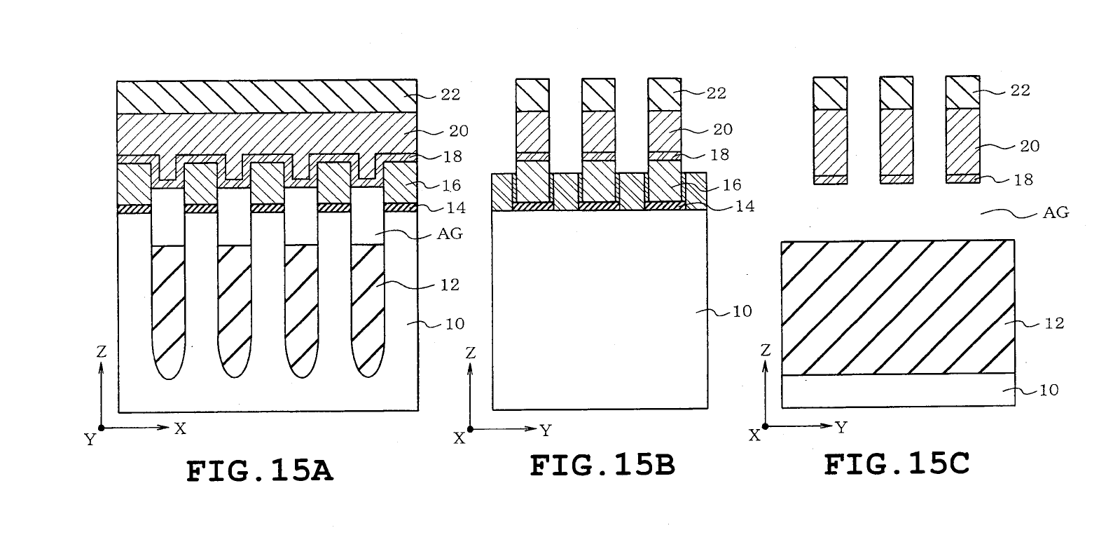

Then, air gaps AG are formed by removing the upper portions of element insulating films 12 by wet etching as illustrated in FIGS. 15A, 15B, and 15C. A diluted fluoric acid solution may be used for example in the wet etching. The depth of air gaps AG may be controlled by adjustment of the duration of wet etching.

The subsequent process steps are similar to process steps employed in known NAND flash memory devices 100 and therefore, peripheral circuit transistors, interlayer insulating films, upper metal wirings, and the like are formed using known methods.

NAND flash memory device 100 of the present embodiment is formed by the above described process steps.

### Other Embodiments

In the above described embodiment, an example of NAND flash memory device application was disclosed, however, other embodiments may be directed to nonvolatile semiconductor storage devices such as NOR flash memory device and EPROM, or to semiconductor storage devices such as DRAM or SRAM, or further to logic semiconductor devices such as a microcomputer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a semiconductor substrate;
an active region provided in the semiconductor substrate and extending in a first direction; and
a plurality of gates provided above the active region and extending in a second direction;
the gates being provided with a stack of a floating gate and a control gate, and
an elevated portion provided above the active region disposed between adjacent gates.

2. The semiconductor storage device according to claim 1, wherein the elevated portion is formed of silicon.

3. The semiconductor storage device according to claim 2, wherein the elevated portion is formed by selective epitaxial growth.

4. The semiconductor storage device according to claim 3, wherein the elevated portion is provided with a facet.

5. The semiconductor storage device according to claim 1, wherein the elevated portion is free of impurities.

6. The semiconductor storage device according to claim 3, wherein the elevated portion is shaped substantially as a quadrangular prism.

7. The semiconductor storage device according to claim 3, wherein the elevated portion is shaped substantially as a quadrangular pyramid.

8. The semiconductor storage device according to claim 3, wherein the elevated portion is shaped substantially as a quadrangular frustum pyramid.

9. The semiconductor storage device according to claim 3, wherein the elevated portion is shaped substantially as a hipped roof.

10. The semiconductor storage device according to claim 3, wherein the elevated portion is provided with an upper surface portion and a side surface portion.

11. The semiconductor storage device according to claim 10, wherein the upper surface portion and the side surface portion allows formation of an inversion layer therein.

12. The semiconductor storage device according to claim 3, wherein the elevated portion is provided with a sloped surface portion.

13. The semiconductor storage device according to claim 12, wherein the sloped surface portion allows formation of an inversion layer therein.

14. The semiconductor storage device according to claim 3, wherein the elevated portion is provided with an upper surface portion and a sloped surface portion.

15. The semiconductor storage device according to claim 14, wherein the upper surface portion and the sloped surface portion allows formation of an inversion layer therein.

16. The semiconductor storage device according to claim 3, wherein the elevated portion has a triangular cross section in the second direction.

17. The semiconductor storage device according to claim 3, wherein the elevated portion has a trapezoid cross section in the second direction.

18. A method of manufacturing a semiconductor storage device comprising:
forming, in a semiconductor substrate, an active region extending in a first direction;
forming, above the semiconductor substrate, memory cell gates extending in a second direction and having a stack of a floating gate and a control gate;
forming an insulating film along side surfaces of the memory cell gates;
forming an elevated portion in the active region disposed between the memory cell gates.

19. The method of manufacturing a semiconductor storage device according to claim 18, wherein the elevated portion is formed by a selective epitaxial growth of silicon.

20. The method of manufacturing a semiconductor storage device according to claim 18, wherein the elevated portion is formed by a selective epitaxial growth of silicon so as to produce a facet.
